(19) United States
(12) Patent Application Publication
(10) Pub. No.: US 2025/0126935 A1
(43) Pub. Date: Apr. 17, 2025

(54) LIGHT EMITTING ELEMENT AND LIGHT EMITTING DEVICE

(71) Applicant: TOYODA GOSEI CO., LTD., Kiyosu-shi (JP)

(72) Inventors: Shinichi MATSUI, Kiyosu-shi (JP); Hideki OMOYA, Kiyosu-shi (JP); Koichi MIZUTANI, Kiyosu-shi (JP); Hiroaki MAKINO, Kiyosu-shi (JP); Masaki OYA, Kiyosu-shi (JP)

(21) Appl. No.: 18/906,794

(22) Filed: Oct. 4, 2024

(30) Foreign Application Priority Data
Oct. 16, 2023 (JP) 2023-178109
Aug. 8, 2024 (JP) 2024-133306

(51) Int. Cl. H01L 33/46; H01L 33/32; H01L 33/38

(52) U.S. Cl. CPC H10H 20/841; H10H 20/825; H10H 20/831

(57) ABSTRACT

A light emitting element with improved light output and lifetime. The light emitting element using a group III nitride semiconductor containing Al and having an emission wavelength of 200 to 280 nm includes a substrate, a semiconductor layer formed of an n n-type layer, a light emitting layer, and a p-type layer deposited in this order on the substrate, a hole formed in a predetermined region on the surface of the p-type layer and having a depth reaching the n-type layer, a p-electrode formed on and in contact with the p-type layer and having a reflectance of 50% or more for ultraviolet light with an emission wavelength, and an n-electrode formed on or above the n-type layer exposed at the bottom of the hole. The hole and the n-electrode have a pattern with a plurality of dots arranged two-dimensionally, and the area of the p-electrode is 0.75 mm² or more.

### BACKGROUND OF THE INVENTION

### Cross-Reference

This application claims priority to Japanese patent applications No. 2023-178109 filed on Oct. 16, 2023 and No. 2024-133306 filed on Aug. 8, 2024, the contents of which are incorporated herein by reference.

### Technical Field

The present disclosure relates to a light emitting element and a light emitting device.

### Background Art

A sterilization device that kill bacteria and viruses in running water by irradiating ultraviolet rays is known. A mercury lamp is widely used as a light source. The mercury lamp uses mercury, and thus has strong toxicity and a large environmental load, which is a problem. There is also a problem that a sterilization device using the mercury lamp becomes large.

On the other hand, the wavelength of ultraviolet light emitting element using group III nitride semiconductor corresponds to the wavelength band in a range of approximately 210 nm to 400 nm. UVC (wavelength of 100 nm to 280 nm) is known to enable efficient sterilization and disinfection, and using UVC to disinfect and sterilize water and air is attracting attention. Accordingly, the mercury lamp is being replaced by light emitting element using group III nitride semiconductor with an emission wavelength of UVC.

JP-A-2017-513234 and WO-A1-2010/146808 disclose a structure in which an n-electrode has a pattern in which a plurality of dots is arranged two-dimensionally in a light emitting element using a group III nitride semiconductor.

### SUMMARY OF THE INVENTION

However, a conventional UVC light emitting element has not reached the performance required to replace the mercury lamp, in terms of light output and lifetime. A light emitting device in which a UVC light emitting element is mounted on a sub-mount also needed to be improved in terms of light output.

The present disclosure has been made in view of such a background. Firstly, an object thereof is to provide a light emitting element with improved light output and lifetime. Secondly, an object thereof is to provide a light emitting device in which a light emitting element is mounted on a sub-mount, and in which the light output is improved.

One aspect of the present disclosure is directed to
a light emitting element using group III nitride semiconductor containing Al and having an emission wavelength of 200 nm to 280 nm, the light emitting element including:
a substrate;
a semiconductor layer formed of an n-type layer, a light emitting layer, and a p-type layer deposited in this order on the substrate;
a hole formed in a predetermined region on the surface of the p-type layer and having a depth reaching the n-type layer;
a p-electrode formed on and in contact with the p-type layer and having a reflectance of 50% or more for ultraviolet light with an emission wavelength;
an n-electrode formed on or above the n-type layer exposed at the bottom of the hole, wherein
the hole and the n-electrode are in a pattern with a plurality of dots arranged two-dimensionally, and
the area of the p-electrode is 0.75 mm² or more.

Another aspect of the present disclosure is directed to
a light emitting device including:
the light emitting element according to the above aspect; and
a sub-mount with the light emitting element flip-chip mounted thereon and having a reflective layer on the surface of the mounting side, wherein
the reflective layer has a reflectance of 50% or more for ultraviolet light with an emission wavelength of the light emitting element, and
the reflective layer is formed in a region of at least 0 μm to 500 μm outward from the side end surface of the light emitting element, in a plan view.

The other aspect of the present disclosure is directed to
a light emitting device including:
a light emitting element using a group III nitride semiconductor containing Al and having an emission wavelength of 200 nm to 280 nm,
a flat plate sub-mount with the light emitting element flip-chip mounted and having a reflective layer formed on the surface of the mounting side and a frontside electrode layer connected to the light emitting element, wherein
the reflective layer has an insulating layer as a bottom layer,
a part of the frontside electrode layer is formed outside of the side end surface of the light emitting element, in a plan view,
the reflective layer has a reflectance of 50% or more for ultraviolet light with an emission wavelength of the light emitting element, and
the reflective layer is formed in a region of at least 0 μm to 500 μm outward from the side end surface of the light emitting element, in a plan view.

In the light emitting element according to the above aspects, the n-electrode has a pattern with a plurality of dots arranged two-dimensionally. Therefore, the area of the p-electrode can be made wider. That is, the area of the p-electrode is 0.75 mm² or more. This can improve light output and lifetime. In the light emitting device according to the above aspects, the reflective layer is formed in a region of at least 0 μm to 500 μm outward from the side end surface of the light emitting element, in a plan view. Therefore, the light output can be improved.

### BRIEF DESCRIPTION OF THE DRAWINGS

FIG. 1 is a cross-sectional view of a configuration of a light emitting element in a first embodiment, in a direction perpendicular to a main surface of a substrate;

FIG. 2 is a view showing a plan view shape of an electrode of the light emitting element in the first embodiment;

FIG. 3 shows the relationship between area of p-electrode and light output;

FIG. 4 shows the relationship between area of p-electrode and lifetime;

FIG. 5 is a cross-sectional view of the light emitting element in a variation of the first embodiment, in a direction perpendicular to a main surface of a substrate;

FIG. 6 is a view showing a plan view shape of an electrode of a light emitting element in a variation of the first embodiment;

FIG. 7 is a view showing a plan view shape of an electrode of a light emitting element in a variation of the first embodiment;

FIG. 8 is a view showing a plan view shape of an electrode of a light emitting element in a variation of the first embodiment;

FIG. 9 is a cross-sectional view of a configuration of a light emitting device in a second embodiment, in a direction perpendicular to a main surface of a sub-mount;

FIG. 10 is a plan view of a sub-mount viewed from above;

FIG. 11 is a cross-sectional view of a configuration of a first reflective layer, in a direction perpendicular to the main surface of the sub-mount; and

FIG. 12 shows radiation intensity on a top surface of the sub-mount.

### DETAILED DESCRIPTION OF PREFERRED EMBODIMENTS

A light emitting element is made of a group III nitride semiconductor containing Al and has an emission wavelength of 200 nm to 280 nm. The light emitting element has a substrate, a semiconductor layer formed of an n-type layer, a light emitting layer, and a p-type layer deposited in this order on the substrate, a hole formed in a predetermined region on the surface of the p-type layer and having a depth reaching the n-type layer, a p-electrode formed on and in contact with the p-type layer and having a reflectance of 50% or more for ultraviolet light with an emission wavelength, and an n-electrode formed on or above the n-type layer exposed at the bottom of the hole. Furthermore, the hole and the n-electrode have a pattern with a plurality of dots arranged two-dimensionally. The area of the p-electrode is 0.75 mm² or more.

In the above light emitting element, the diameter of the dot of the n-electrode may be 5 μm to 100 μm, and the distance between the centers of adjacent dots may be 50 μm to 200 μm. Thus, in-plane current diffusion can be improved while sufficiently ensuring the area of the p-electrode.

In the above light emitting element, a ratio of the area of the p-electrode to a total area of the holes and the p-type layer may be 70% or more, in a plan view. The reflection of ultraviolet light by the p-electrode can be increased, thereby improving the light extraction efficiency.

In the above light emitting element, the overall thickness of the light emitting element may be 0.5 mm to 1 mm. Thus, the light output and the lifetime can be improved.

In the above light emitting element, a p-pad electrode is formed on or above the p-electrode and an n-pad electrode is formed on or above the n-electrode, and the total area of the p-pad electrode and n-pad electrode may be 0.7 mm² or larger. The contact area between the light emitting element and the mounting substrate is increased, thereby improving heat dissipation. As a result, the lifetime can be improved.

In the above light emitting element, the area of the p-electrode, the diameter of the dot of the n-electrode, and the distance between the centers of adjacent dots may be set so that the light output is 150 mW or more and the lifetime is 10,000 hours or more when driven at 350 mA.

The light emitting device includes the above light emitting element and a sub-mount on which the light emitting element is flip-chip mounted and which has a reflective layer formed on the surface of the mounting side. The reflective layer has a reflectance of 50% or more for ultraviolet light with an emission wavelength of the light emitting element, and the reflective layer is formed in a region of at least 0 μm to 500 μm outward from the side end surface of the light emitting element.

In the above light emitting device, the reflective layer may be formed in an entire region of 0 μm or more outward from the side end surface of the light emitting element, in a plan view. The light output can be further improved.

In the above light emitting device, the sub-mount may have a frontside electrode layer connected to the light emitting element, the reflective layer may have an insulating layer as a bottom layer, and a part of the frontside electrode layer may be formed outside the side end surface of the light emitting element, in a plan view.

In the above light emitting device, the reflective layer may include an insulating layer, and a metal reflective layer formed on or above the insulating layer and made of a metal having a reflectance of 50% or more for ultraviolet light with an emission wavelength of the light emitting element.

In the above light emitting device, the reflective layer may include a Distributed Bragg Reflector (hereinafter referred to as “DBR”) reflective layer having a reflectance of 90% or more for ultraviolet light with an emission wavelength of the light emitting element.

In the above light emitting device, the reflective layer may include an insulating layer, a metal reflective layer formed on or above the insulating layer and made of a metal having a reflectance of 50% or more for ultraviolet light with an emission wavelength of the light emitting element, and a DBR layer formed on or above the metal reflective layer and having a reflectance of 50% or more for ultraviolet light with an emission wavelength of the light emitting element.

In the above light emitting device, the thickness of the substrate of the light emitting element may be 900 μm or more.

The light emitting device includes a light emitting element using a group III nitride semiconductor containing Al and having an emission wavelength of 200 nm to 280 nm, and a flat plate sub-mount on which the light emitting device is flip-chip mounted and which has a reflective layer formed on the surface of the mounting side and a frontside electrode layer connected to the light emitting element. The reflective layer has an insulating layer as a bottom layer, a part of the frontside electrode layer is formed outside the side end surface of the light emitting element in a plan view, the reflective layer has a reflectance of 50% or more for ultraviolet light with an emission wavelength of the light emitting element, and the reflective layer is formed in a region of at least 0 μm to 500 μm outward from the side end surface of the light emitting element, in a plan view.

### First Embodiment

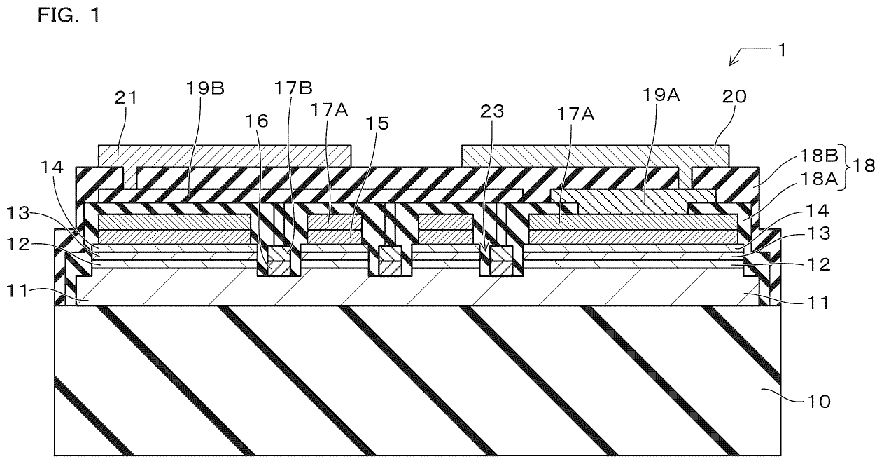

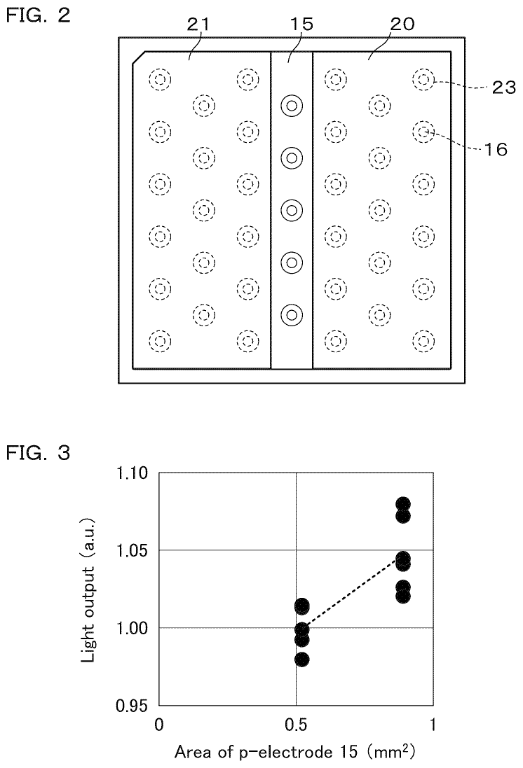

FIG. 1 is a cross-sectional view of a configuration of a light emitting element in a first embodiment, in a direction perpendicular to a main surface of a substrate 10. FIG. 2 is a view showing a plan view shape of an electrode of the light emitting element in the first embodiment. The light emitting element in the first embodiment constitutes a flip-chip type ultraviolet light emitting device. The light emitting element 1 has an emission wavelength of UVC, for example, 200 nm to 280 nm.

### 1. Configuration of Light Emitting Element 1

As shown in FIG. 1, the light emitting element 1 in the first embodiment includes a substrate 10, an n-type layer 11, a light emitting layer 12, an electron blocking layer 13, a p-type layer 14, a p-electrode 15, an n-electrode 16, an intermediate electrode 17A and 17B, a protective film 18, a p-wiring electrodes 19A and an n-wiring electrode 19B, a p-pad electrode 20, and an n-pad electrode 21. Each part of the configuration is described below. A laminate of the n-type layer 11, the light emitting layer 12, the electron blocking layer 13, and the p-type layer 14 may be hereinafter referred to as a semiconductor layer.

The substrate 10 is a substrate made of sapphire having a c-plane main surface. Any material other than sapphire may be used as long as the material has high transmittance with respect to an emission wavelength and is capable of growing group III nitride semiconductor thereon. The thickness of the substrate 10 is preferably 0.5 mm to 1 mm. This can improve the light extraction efficiency.

The rear surface of the substrate 10 may be provided with an anti-reflective film. The rear surface of the substrate 10 corresponds to a surface opposite to the n-type layer 11 side and corresponds to the light output side. By providing an anti-reflective film, ultraviolet light is prevented from being reflected on the rear surface of the substrate 10 and returned to the element side, thereby improving the light extraction efficiency. The anti-reflective film is made of, for example, SiO₂ whose thickness is ¼ of the emission wavelength.

The n-type layer 11 is disposed on the substrate 10 through a buffer layer (not illustrated). The n-type layer 11 is made of n-AlGaN. The n-type impurity is Si, and the n-type layer 11 has a Si concentration of 5×10¹⁸/cm³ to 5×10¹⁹/cm³. The n-type layer 11 may be formed of a plurality of layers.

The light emitting layer 12 is disposed on the n-type layer 11. The light emitting layer 12 has an MQW structure in which a well layer and a barrier layer are alternately and repeatedly deposited. The number of repetitions is, for example, 2 to 5. The well layer is made of AlGaN, and its Al composition is set according to a desired emission wavelength. The barrier layer is made of AlGaN having an Al composition higher than that of the well layer. The barrier layer may be made of AlGaInN having a band gap energy larger than that of the well layer. The light emitting layer 12 may have an SQW structure.

The electron blocking layer 13 is disposed on the light emitting layer 12. The electron blocking layer 13 is made of p-AlGaN having an Al composition higher than that of the barrier layer of the light emitting layer 12. The electron blocking layer 13 prevents electrons injected from the n-electrode 16 from diffusing beyond the light emitting layer 12 to the p-type layer 14.

The p-type layer 14 is disposed on the electron blocking layer 13. The p-type layer 14 is made of p-AlGaN. In the light emitting element 1 in the first embodiment, all semiconductor layers from the n-type layer 11 to the p-type layer 14 are made of AlGaN. This suppresses absorption of ultraviolet light by the semiconductor layers. The p-type layer 14 has an Al composition of, for example, 5% to 80%. The p-type impurity is Mg. The p-type layer 14 has a Mg concentration of 1×10¹⁹/cm³. The p-type layer may be formed of a plurality of layers having different Al composition or Mg concentration. In such a case, the layer in contact with the p-electrode 15 may be made of p-AlGaN having an Al composition of 5% to 80%. The p-type layer 14 is not limited to being made of AlGaN, but may be made of AlGaInN, as long as it is made of a group III nitride semiconductor containing Al.

The top layer of the p-type layer 14 formed of a plurality of layers, may be made of thin GaN with a thickness of one molecular layer or more but 50 nm or less. The top layer of the p-type layer 14 constitutes a contact layer in contact with the p-electrode 15.

A hole 23 having a depth reaching the n-type layer 11 is formed in a part of the surface of the p-type layer 14. The holes 23 have a dot pattern, and a plurality of holes 23 is arranged in a lattice shape (see FIG. 2). The n-type layer 11 is exposed at the bottom of the hole 23. By arranging the holes 23 in a dot pattern to expose the n-type layer 11, in-plane uniformity of light emission can be obtained. Furthermore, by arranging the holes 23 in a dot-like pattern, the reduction of the light emitting area (area of the p-type layer 14) due to the holes 23 is minimized as much as possible and the area of the p-electrode 15 is widened to improve the light output.

The plan view shape of each hole 23 is a circle. Each hole 23 may be formed in any other polygonal shape such as a square or a regular hexagon. In the case of a regular hexagon, the side surface of the hole 23 preferably has a m-plane. The arrangement pattern of the holes 23 is an equilateral triangular lattice shape. The arrangement pattern of the holes 23 may also be any other two-dimensional arrangement pattern such as a square lattice or honeycomb shape. Preferably, it is an equilateral triangular or square lattice shape.

The diameter of the hole 23 is preferably 5 μm to 100 μm. The distance between the centers of adjacent holes 23 is preferably 50 μm to 200 μm. By setting the diameter and spacing of the holes 23 in this manner, in-plane current diffusion can be improved while sufficiently ensuring the area of the p-electrode. Here, the diameter of the hole 23 is the diameter of the circumscribed circle of the hole 23.

The p-electrode 15 is formed on and in contact with the p-type layer 14. The p-electrode 15 is formed on the p-type layer 14, except for the region where the holes 23 are formed and the vicinity of the edges of the p-type layer 14 (see FIG. 2). This makes the light emitting area larger. The p-electrode 15 constitutes a reflective electrode to increase the light extraction efficiency by reflecting ultraviolet light emitted from the emitting layer 12 toward the substrate 10. The p-electrode 15 is made of a material having a reflectance of 50% or more for ultraviolet light with an emission wavelength. For example, it is made of Ru, Rh, an alloy containing Ru or Rh as a main component, ITO/Al, and the like. Ru and Rh have a high reflectance for UVC and low contact resistance to the p-type contact layer 14 made of p-AlGaN. Therefore, it is suitable as the p-electrode 15 in the UVC light emitting element 1. The reflectance is more preferably 70% or more.

The p-electrode 15 has an area of 0.75 mm² or more. The area of the element, the diameter and arrangement pattern of the hole 23 are set to satisfy the above. This improves the light output and lifetime of the light emitting element 1 in the first embodiment. The light output is improved because the area being reflected by the p-electrode 15 is increased. The lifetime is improved because the current density is reduced due to an increase in the area of the p-electrode 15.

In particular, by setting the area of the p-electrode 15 to 0.75 mm² or more, the light emitting element 1 in the first embodiment can perform well enough to replace a mercury lamp. To replace the mercury lamp with the light emitting element 1, a light output of 150 mW when driven at 350 mA and a lifetime of 1000 hours when driven at 350 mA are required. The p-electrode 15 can achieve this performance by setting the area of the p-electrode 15 to 0.75 mm² or more.

The p-electrode 15 preferably has an area of 8 mm² or less. If the area of the p-electrode 15 is too large, the probability that the semiconductor layer has a crystal defect is increased and the production yield decreases.

The area of the p-electrode 15 is preferably 70% or more of the area of the element (a total area of the p-type layer 14 and the holes 23). This can increase the reflection of ultraviolet light by the p-type layer 15 and improve the light extraction efficiency. The area of the p-electrode 15 is preferably less than 95% of the area of the element. This is to sufficiently ensure the area of hole 23 and in-plane current diffusion is not deteriorated.

The n-electrode 16 is formed on or above the n-type layer 11 exposed at the bottom of each hole 23. Therefore, the n-electrode 16 has a pattern in which a plurality of dots is arranged (see FIG. 2).

The plan view shape of the dot of the n-electrode 16 has a shape that is a reduced size of the plan view shape of the hole 23. If the plan view of the hole 23 is a circle, the plan view of the n-electrode 16 is a circle with a diameter smaller than the diameter of the hole 23, and the arrangement pattern of the dots of the n-electrode 16 is the same as that of the hole 23. Since the n-electrode 16 has a pattern in which a plurality of dots is arranged two-dimensionally in this manner, the in-plane current diffusion can be improved while enlarging the region for forming the p-electrode 15.

The n-electrode 16 is made of a heat-treated V/Al/Ti structure. The n-electrode 16 may also be formed of Ti/Al/Ti and others. Specifically, the heat-treated V/Al/Ti structure has a structure in which a layer made of AlNₓ, a layer made of a metal containing Al and containing V and Ti, and a layer made of Ti, are deposited in this order.

The layer made of AlNₓ has a thickness of 1 nm to 3 nm. x is, for example, 0.4 to 0.7. Further, x may decrease as a distance from the n-type layer 11 increases in a thickness direction. In this case, an average of x in the thickness direction is 0.4 to 0.7. Ga may be diffused from the n-type layer 11, and in this case, the layer made of AlNₓ is made of Al_{y}Ga_{1-y}Nₓ (0.4≤x≤0.7) having an Al composition higher than that of the n-type layer 11. When the Al composition of the n-type layer 11 is a, the relation is a<y≤1. y is, for example, 0.7 or higher. In this case, x may decrease as the distance from the n-type layer 11 increases in the thickness direction, and y may increase as the distance from the n-type layer 11 increases in the thickness direction.

The layer made of a metal containing Al and containing V and Ti, has a thickness of 50 nm to 500 nm. The ratio of Al, V, and Ti is, for example, 50 mol % to 85 mol % for Al, 5 mol % to 20 mol % for V, and 10 mol % to 30 mol % for Ti.

In the n-electrode 16 having the above structure, the contact resistance to the n-type layer 11 is reduced. For example, the contact resistivity of the n-electrode 16 to the n-type layer 11 is 4×10⁻⁴ Ω·cm² or less. The reason for this is considered to be, firstly, that the layer made of AlNₓ functions as a good contact layer to the n-type layer 11. Secondly, it is considered that nitrogen vacancies are generated on a surface of the n-type layer 11, and the contact resistance is reduced because it becomes n-type.

The layer made of Ti is provided as a cover to prevent Al in the n-electrode 16 from evaporating during alloying. TiN, Ni, Pt, Au, or the like may be used, other than Ti.

An intermediate electrodes 17A and 17B are formed on the p-electrode 15 and the n-electrode 16, respectively. The plan view shape of the intermediate electrode 17A is the same as that of the p-electrode 15. The plan view shape of the intermediate electrode 17B is the same as that of the n-electrode 16, and has a pattern in which a plurality of dots is arranged. The intermediate electrodes 17A and 17B are made of, for example, Ti/Ni/Au/Al.

The intermediate electrodes 17A and 17B may be omitted, and a p-wiring electrode 19A and the p-electrode 15 may be directly connected, and an n-wiring electrode 19B and the n-electrode 16 may be directly connected.

The protective film 18 is formed to cover the entire top surface of the element. That is, the protective film 18 is continuously formed on side surfaces and surfaces of the p-electrode 15 and n-electrode 16, the surface and a side surface of the semiconductor layer, a side surface of an element isolation groove, and the inside of the holes 23. The protective film 18 has a structure in which the first protective film 18A and a second protective film 18B are deposited in this order on the semiconductor layer side.

The protective film 18 is made of an insulator, for example, SiO₂. Other materials such as SiN, Al₂O₃, TiO₂, and AlN may also be used. A deposited layer of a plurality of materials may be used. The first protective film 18A and the second protective film 18B may be made of different materials.

The p-wiring electrode 19A and the n-wiring electrode 19B are formed between the first protective film 18A and the second protective film 18B. The p-wiring electrode 19A is connected to the intermediate electrode 17A via a hole formed in the first protective film 18A and to the p-pad electrode 20 via a hole formed in the second protective film 18B. The n-wiring electrode 19B is connected to the p-pad electrode 20 via a hole formed in the second protective film 18B. The n-wiring electrode 19B is connected to each intermediate electrode 17B via holes formed in the first protective film 18A and to the n-pad electrode 21 via a hole formed in the second protective film 18B. The p-electrode 19A and the n-electrode 19B are made of, for example, Ti/Ni/Au/Al.

By providing the p-wiring electrodes 19A and the n-wiring electrodes 19B between the intermediate electrodes 17A and 17B and the p-pad electrodes 20 and the n-electrode pad electrodes 21, the shape of the p-electrode pad 20 and the n-electrode pad 21 can be set freely. In addition, since the holes 23 can be arranged over the entire surface, in-plane uniformity of light emission can be improved.

The p-pad electrode 20 and the n-pad electrode 21 are spaced apart from each other on the protective film 18. The p-pad electrode 20 is connected to the p-wiring electrode 19A via a hole formed in the second protective film 18B. The n-pad electrode 21 is connected to the n-wiring electrode 19B via a hole formed in the second protective film 18B. The p-pad electrode 20 and n-electrode pad electrode 21 are made of, for example, Ti/Pt/Au/AuSn.

As shown in FIG. 2, the p-pad electrode 20 and the n-pad electrode 21 are arranged within a small rectangular shape slightly inside the outer rectangular shape of the light emitting element 1. The p-pad electrode 20 and the n-pad electrode 21 have regions obtained by dividing the small rectangular shape. The p-pad electrode 20 and the n-pad electrode 21 have a region divided into two equal parts by a band-shaped boundary region along a straight line parallel to one side of the small rectangular shape. In FIG. 2, the band-shaped boundary region has a shape extending in the up-down direction at the center of the left-right direction.

A total area of the p-pad electrode 20 and the n-pad electrode 21 is preferably 0.7 mm² or more. A contact area between the light emitting element 1 and the mounting substrate in the first embodiment is increased, and heat dissipation can be improved. As a result, lifetime can be improved. For the same reason, a ratio of the total area of the p-pad electrode 20 and the n-pad electrode 21 to a light emitting area (an area of the p-electrode 15) is preferably 70% or more.

An overall thickness of the light emitting element 1 in the first embodiment (a distance from the rear surface of the substrate 10 to the surface of the p-pad electrode 20 and the n-pad electrode 21) is preferably 0.5 mm to 1 mm. Within this range, light output and lifetime can be improved.

In the light emitting element 1 in the first embodiment above, the n-electrode 16 has a pattern in which a plurality of dots is two-dimensionally arranged. This reduces the area of the n-electrode 16 and enlarges the area of the p-electrode 15 without deteriorating in-plane current diffusion. The p-electrode 15 has an area of 0.75 mm² or more. This improves light output and lifetime of the light emitting element 1. In particular, it is possible to achieve a light output of 150 mW when driven at 350 mA and a lifetime of 1,000 hours when driven at 350 mA, which is the performance required to replace mercury lamps. Here, the lifetime is defined as a time until the light output reaches 70% of the light output at initial driving.

### 2. Experimental Results

Next, the results of experiments on the light emitting element 1 in the first embodiment will be described.

Light emitting elements were manufactured, in which the area of the p-electrode 15 was varied to various values, and light output and lifetime were measured when driven at 350 mA. The area of the p-electrode 15 was varied according to the outer shape of the p-electrode 15, and the diameters of the hole 23 and the n-electrode 16. The lifetime was defined as a time until the light output reaches 70% of the light output at initial driving when driven at 350 mA.

FIG. 3 shows the relationship between the area of the p-electrode 15 and the light output. The vertical axis of the graph shows a value standardized as “1” when the light output is 150 mW. As shown in FIG. 3, it was found that the larger the area of the p-electrode 15, the larger the light output tends to be. The light output required to replace the mercury lamp is 150 mW when driven at 350 mA. FIG. 3 reveals that this requirement can be achieved if the area of the p-electrode 15 is 0.5 mm² or larger.

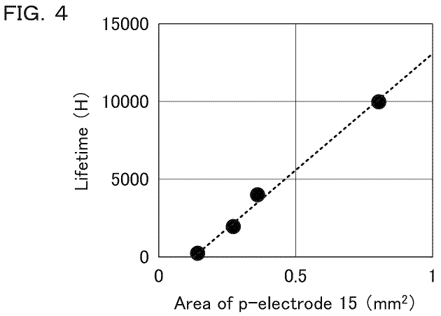

FIG. 4 shows the relationship between the area of the p-electrode 15 and the lifetime. As shown in FIG. 4, the lifetime increases linearly with the increase in the area of the p-electrode 15. The lifetime required to replace the mercury lamp is 10,000 hours when driven at 350 mA. FIG. 4 reveals that the lifetime exceeds 10,000 hours when the area of the p-electrode 15 is 0.75 mm² or more.

As shown in FIG. 3 and FIG. 4, it has been found that the area of the p-electrode 15 is 0.75 mm² or more to satisfy the light output and the lifetime required to replace the mercury lamp.

### Variations of First Embodiment

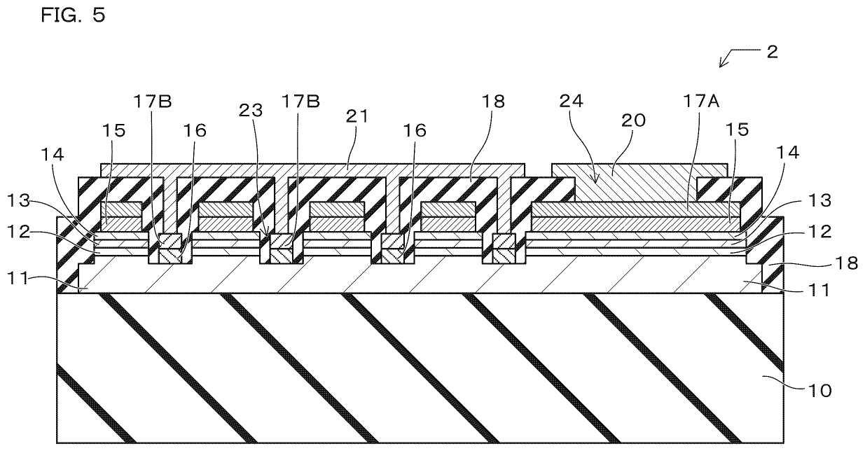

FIG. 5 is a cross-sectional view of a configuration of a light emitting element 2 in a variation of the first embodiment, in a direction perpendicular to a main surface of a substrate. As shown in FIG. 5, in the light emitting element 2 in a variation a p-electrode 19A and an n-electrode 19B are omitted from the light emitting element 1 in the first embodiment. In the light emitting element 2, a plan view shapes of a p-electrode 15, an n-electrode 16, a p-pad electrode 20, and an n-pad electrode 21 are changed from those of the light emitting element 1 in the first embodiment. The light emitting element 2 has a configuration in which an intermediate electrode 17A is connected to the p-pad electrode 20 and an intermediate electrode 17B is connected to the n-pad electrode 21.

If a p-wiring electrode 19A and an n-wiring electrode 19B are omitted, the configuration of the light emitting element 2 can be simplified, although the shape of the n-electrode 16, the p-pad electrode 20, and the n-pad electrode 21 will be limited.

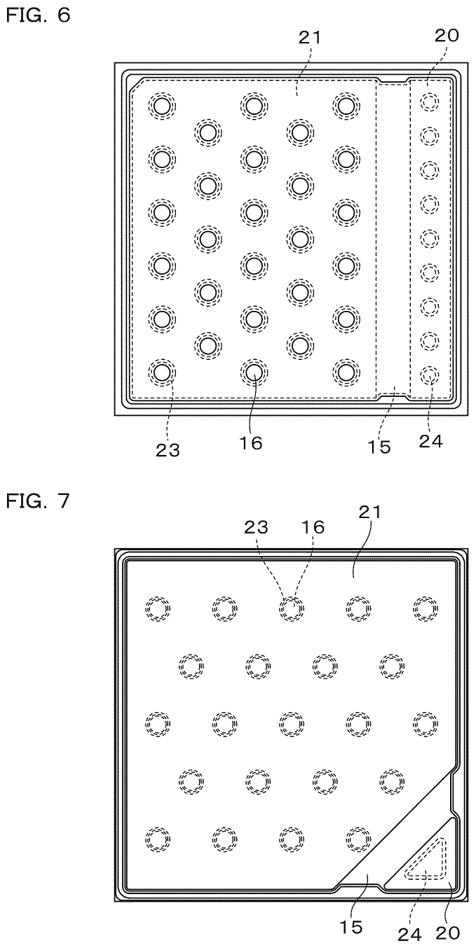

FIGS. 6 to 8 show various electrode shapes in the light emitting element 2 in the variation shown in FIG. 5. The electrode shapes shown in FIGS. 6 to 8 are explained below.

The electrode shape shown in FIG. 6 is as follows: the p-pad electrode 20 and the n-pad electrode 21 are disposed within a small rectangular shape slightly inside the outer rectangular shape of the light emitting element 2 in a plan view. The p-pad electrode 20 and the n-pad electrode 21 have regions obtained by dividing the small rectangular shape into two unequal parts. The p-pad electrode 20 and the n-electrode pad 21 are divided into two by a straight boundary region along the edge in a vicinity of the edge of the light emitting element 2. In FIG. 6, the straight boundary region has a shape extending vertically in the right side of the left-right direction. The smaller area is the p-pad electrode 20 and the larger area is the n-pad electrode 21. The n-pad electrode 21 is formed in a wide rectangle shape and the p-pad electrode 20 is formed in a long rectangle shape.

A Hole 23 and the n-electrode 16 have a circular dot shape and arranged in an equilateral triangular lattice in a region under the n-pad electrode 21. The hole 23 and the n-electrode pad 16 are not arranged in a region under the p-pad electrode 20 and the linear region.

A hole 24 for connecting the p-electrode 15 to the p-pad electrode 20 is formed inside the p-pad electrode 20 in a plan view. The holes 24 have a circular dot shape and are arranged at predetermined intervals in a straight line along the edge of the light emitting element 2.

The electrode shape shown in FIG. 7 is as follows. The electrode shape shown in FIG. 7 is an example different from the electrode shape shown in FIG. 6. The p-pad electrode 20 and the n-pad electrode 21 are arranged in a small rectangular shape slightly inside the outer rectangular shape of the light emitting element 2 in a plan view. The p-pad electrode 20 and the n-electrode pad 21 have regions obtained by dividing the small rectangular shape into unequal parts. The p-pad electrode 20 and the n-electrode pad 21 are divided into two by a boundary region along a straight line forming an angle of 45° to the sides of the rectangle at a corner of the rectangle. One part forming a right-angled isosceles triangle is the p-electrode pad electrode 20, and the other part (a pentagon with the corner of the rectangle cut off) is the n-pad electrode 21.

Similarly as in FIG. 6, the hole 23 and the n-electrode 16 have a circular dot shape and are arranged in an equilateral triangular 1 in a region under the n-pad electrode 21. The hole 23 and the n-electrode pad 16 are not arranged in a region under the p-pad electrode 20 and the linear region.

The hole 24 for connecting the p-electrode 15 to the p-pad electrode 20 is formed inside the p-pad electrode 20 in a plan view, and has the shape of a reduced right-angled isosceles triangle of the p-pad electrode 20.

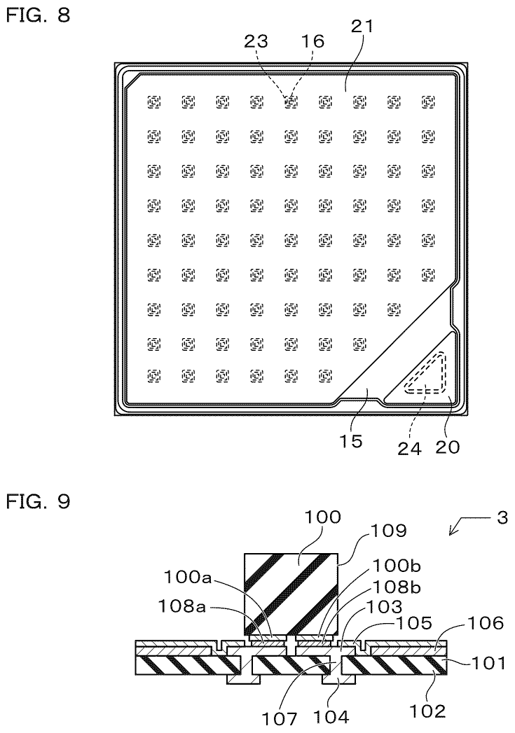

The electrode shape shown in FIG. 8 is as follows. The electrode shape shown in FIG. 8 is an example different from the electrode shapes shown in FIGS. 6 and 7. In FIG. 8, a plan view shape of the dots of the hole 23 and the n-electrode 16 in FIG. 7 is changed from a circle to a square, and the diameter and spacing of the dots are reduced. Otherwise, it is the same as FIG. 7.

By using any one of the electrode shapes shown in FIGS. 6 to 8, a total area of the p-pad electrode 20 and the n-pad electrode 21 can be made large, thereby improving heat dissipation.

Even in the light emitting element 2 in the variation described above, the area of the p-electrode 15 can be 0.75 mm² or more, and the light output and the lifetime can be improved. In particular, the light output and the lifetime required to replace the mercury lamp can be achieved.

### Second Embodiment

FIG. 9 is a cross-sectional view of a configuration of a light emitting device 3 in the second embodiment, in a direction perpendicular to a main surface of a sub-mount. As shown in FIG. 9, the light emitting device 3 in the second embodiment has a light emitting element 100 emitting ultraviolet light and a sub-mount 101 formed in a flat plate shape. The light emitting element in the first embodiment can be used as the light emitting element 100. In particular, the substrate of the light emitting element 100 preferably has a thickness of 400 μm or more. This is because light extraction efficiency from the side surface is improved, and light output is enhanced by reflection at a first reflective layer 105 described later. The substrate of the light emitting element 100 has a thickness of more preferably 600 μm or more, and further preferably 900 μm or more. There is no upper limit to the thickness, but it is preferably 2,000 μm or less in consideration of mass production and processability.

The light emitting element 100 constitutes a flip-chip type light emitting device and is flip-chip mounted on the sub-mount 101. The light emitting element 100 has a p-pad electrode 100a and an n-pad electrode 100b. The p-pad electrode 100a and the n-pad electrode 100b are connected to the frontside electrode layers 103 of the sub-mount 101 via junction electrodes 108a and 108b, respectively.

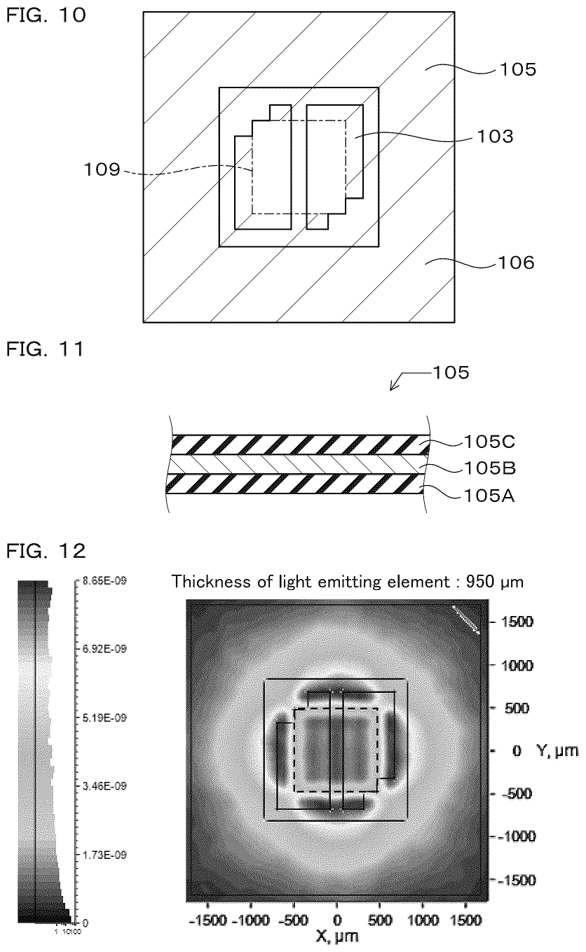

The sub-mount 101 has a substrate layer 102, a frontside electrode layer 103 on the substrate layer 102, a backside electrode layer 104 on the rear surface of the substrate layer 102, a first reflective layer 105, and a second reflective layer 106. FIG. 10 is a plan view of the sub-mount 101 viewed from above.

The substrate layer 102 is formed by using a flat plate made of ceramic and is formed in a square shape in a plan view. Ceramic with high thermal conductivity is preferable. This is to efficiently conduct the heat of the light emitting element 100 to the outside. For example, AlN is preferable.

The frontside electrode layer 103 is formed as two separate layers on the surface of the substrate layer 102. Two frontside electrode layers 103 are connected to the p-pad electrode 100a and the n-pad electrode 100b of the light emitting element 100 via the junction electrodes 108a and 108b. Two frontside electrode layers 103 are made of, for example, Au.

As shown in FIG. 10, two frontside electrode layers 103 are formed in the center of the square of the sub-mount 101 in a plan view. Two frontside electrode layers 103 have a shape similar to a rectangle and are arranged spaced apart. The corners of each rectangle are notched in a staircase shape to align the light emitting elements 100. In a plan view, a part of the two frontside electrode layers 103 is outside a side end surface 109 of the light emitting element 100.

The backside electrode layer 104 is formed as two separate layers on the backside of the substrate layer 102. Two backside electrode layers 104 are connected to two frontside electrode layers 103 via holes 107. Two backside electrode layers 104 are electrically connected to the outside. Two backside electrode layers 104 are made of, for example, Au.

The second reflective layer 106 is formed in a predetermined region of the surface of the substrate layer 102. The second reflective layer 106 constitutes a layer for reflecting ultraviolet light emitted from the light emitting element 100 upward to improve the light output. The second reflective layer 106 is made of, for example, Au. The second reflective layer 106 is made of the same material as the frontside electrode layer 103, allowing the second reflective layer 106 and the frontside electrode layer 103 to be formed simultaneously.

The second reflective layer 106 has a square ring shape in a plan view, as shown in FIG. 10. The frontside electrode layer 103 is disposed inside the inner circumference of the ring of the second reflective layer 106.

The first reflective layer 105 is formed in a predetermined plan view shape on the frontside electrode layer 103, on the substrate layer 102, and on the second reflective layer 106. The first reflective layer 105 constitutes a layer for reflecting ultraviolet light emitted from the light emitting element 100 upward to improve the light output.

As shown in FIG. 11, the first reflective layer 105 has a structure in which a first insulating layer 105A, a metal reflective layer 105B, and a second insulating layer 105C are deposited in this order from the substrate layer 102 side.

The first reflective layer 105 has a reflectance of 50% or more. Here, the reflectance is defined as reflectance for ultraviolet light with an emission wavelength of the light emitting element 100, and is defined as reflectance in the case of perpendicular incidence. Hereinafter, the reflectance means the same unless otherwise specified. The reflectance is more preferably 70% or more, and further preferably 90% or more.

The first insulating layer 105A is made of an insulator, for example, SiO₂. The first insulating layer 105A constitutes a layer provided to ensure insulating properties between the frontside electrode layer 103 and the metal reflective layer 105B. This is because, since the first reflective layer 105 is also provided on the frontside electrode layer 103, the bottom layer needs to be an insulator. The first insulating layer 105A may have a thickness enough to ensure insulating properties between the frontside electrode layer 103 and the metal reflective layer 105B, for example, 500 nm.

The metal reflective layer 105B is made of a metal having a reflectance of 50% or more. The reflectance of the metal reflective layer 105B is more preferably 60% or more, and further preferably 80% or more. The metal reflective layer 105B may be made of, for example, Al, Mg, Ru, Rh, and an alloy mainly composed of these metals. In particular, Al, Mg, or an alloy mainly composed of these metals is preferable due to their high reflectance. The metal reflective layer 105B may have a thickness enough to sufficiently reduce the transmittance of the metal reflective layer 105B, for example, 50 nm or more.

The second insulating layer 105C is made of an insulator. The second insulating layer 105C is made of, for example, SiO₂. The second insulating layer 105C is a layer for protecting the metal reflective layer 105B. The thickness of the second insulating layer 105C is, for example, 200 nm.

The first reflective layer 105 is formed in the shape shown by the diagonal line in FIG. 10. In other words, in a plan view, the first reflective layer 105 is formed in an entire region except for the region of the light emitting element 100 of the square region of the sub-mount 101 (an entire region of 0 μm or more outward from the side end surface 109 of the light emitting element 100). Although a thick substrate of the light emitting element 100 increases the output of ultraviolet light from the side end surface 109, that ultraviolet light can be reflected upward by the first reflective layer 105, thereby improving the light output.

In the second embodiment, the first reflective layer 105 is formed in the entire region of 0 μm or more outward from the side end surface 109 of the light emitting element 100, but it is not limited to this. The first reflective layer 105 may be formed in a region of at least 0 μm to 500 μm outward from the side end surface 109 of the light emitting element 100. In such a region, the emission intensity of ultraviolet light from the light emitting element 100 is higher. Therefore, if the first reflective layer 105 is formed in such a region, the ultraviolet light emitted from the light emitting element 100 can be efficiently reflected upward by the first reflective layer 105, thereby improving light output.

In the second embodiment, the first reflective layer 105 has a structure in which light is reflected by the metal reflective layer 105B, but it may also have a structure in which light is reflected by a DBR (Distributed Bragg reflector) reflective layer, or a combination of the DBR reflective layer and the metal reflective layer 105B. For example, a DBR reflective layer may be provided between the metal reflective layer 105B and the second insulating layer 105C, or a DBR reflective layer may be provided instead of the second insulating layer 105C.

In particular, in terms of angular dependence of the reflectance, the first reflective layer 105 preferably has a combined structure of the DBR reflective layer and the metal reflective layer 105B. The DBR reflective layer has angular dependence of reflectance, and the reflectance is reduced depending on the angle of incidence. On the other hand, the metal reflective layer 105B has no angular dependence of reflectance. Therefore, by providing the first reflective layer 105 with a combined structure of the DBR reflective layer and the metal reflective layer 105B, the reflectance can be increased for any angle of incidence.

The DBR reflective layer is a DBR structure layer in which two or more materials with different refractive indexes from each other are alternately deposited at a predetermined thickness. The reflectance of the DBR reflective layer is set to be preferably 90% or higher, more preferably 95%, and further preferably 98% or more. The DBR reflective layer is made of a material such as SiO₂, TiO₂, HfO₂, Nb₂O₅, ZrO₂, and MgF₂.

In the light emitting device 3 in the second embodiment, the first reflective layer 105 is formed in a region of at least 500 μm or less outward from the side end surface 109 of the light emitting element 100. Therefore, the ultraviolet light emitted from the light emitting element 100 can be efficiently reflected upward by the first reflective layer 105, thereby improving the light output.

Next, the results of the experiments regarding the second embodiment will be described.

### Experiment 1

For the light emitting device 3 in the second embodiment, the radiation intensity on a top surface of the sub-mount 101 was obtained by simulation when the light emitting element 100 emits light. The sub-mount 101 was a square with a side of 3.5 mm in a plan view. The light emitting element 100 was a square with a side of 1.06 mm in a plan view and a thickness of 950 μm.

FIG. 12 shows the radiation intensity (W/μm²) on the top surface of the sub-mount 101. As shown in FIG. 12, it was observed that there is a region of high radiation intensity in the region of 500 μm or less outward from the side end surface 109 of the light emitting element 100. As a result, it was found that the light output can be efficiently improved by forming a reflective layer in a region of 500 μm or less outward from the side end surface 109 of the light emitting element 100.

### Experiment 2

In the second embodiment, the first reflective layer 105 was changed to be formed in a region of 500 μm to 1220 μm outward from the side end surface 109 of the light emitting element 100, and the light output was obtained. The rate of light output improvement was obtained compared with the case when the first reflective layer 105 was not formed. The thickness of the sapphire substrate in the light emitting element 100 was 400 μm to 950 μm. Other conditions were the same as in Experiment 1. As a result, the rate of light output improvement was 0.88% when the thickness of the sapphire substrate was 400 μm—and 2.85% when the thickness of the sapphire substrate was 950 μm. As a result, it was found that the larger the thickness of the substrate, the more effective the light output improvement by the first reflective layer 105.

### Experiment 3

In the second embodiment, the first reflective layer 105 was changed to be formed in a region from 0 μm to 1220 μm outward from the side end surface 109 of the light emitting element 100, and the light output was obtained. The rate of light output improvement was obtained compared with the case when the first reflective layer 105 is not formed. The thickness of the sapphire substrate in the light emitting element 100 was 950 μm. Other conditions were the same as in Experiment 1. As a result, the rate of light output improvement was 3.88%. Comparison with Experiment 2 shows that when the first reflective layer 105 was formed in the region of 0 μm to 500 μm outward from the side end surface 109 of the light emitting element 100, the effect of light output improvement per unit area was higher than when the first reflective layer 105 was formed in the region of 500 μm to 1220 μm outward from the side end surface 109. Therefore, it was found that the first reflective layer 105 is preferably formed at least in a region of at least 0 μm to 500 μm outward from the side end surface 109 of the light emitting element 100.

What is claimed is:

1. A light emitting element using a group III nitride semiconductor containing Al and having an emission wavelength of 200 nm to 280 nm, the light emitting element comprising:
a substrate;
a semiconductor layer formed of an n-type layer, a light emitting layer, and a p-type layer deposited in this order on the substrate;
a hole formed in a predetermined region on the surface of the p-type layer and having a depth reaching the n-type layer;
a p-electrode formed on and in contact with the p-type layer and having a reflectance of 50% or more for ultraviolet light with an emission wavelength; and
an n-electrode formed on or above the n-type layer exposed at the bottom of the hole, wherein
the hole and the n-electrode have a pattern with a plurality of dots arranged two-dimensionally, and
the area of the p-electrode is 0.75 mm² or more.

2. The light emitting element according to claim 1, wherein the diameter of the dot of the n-electrode is 5 μm to 100 μm, and the distance between the centers of adjacent dots is 50 μm to 200 μm.

3. The light emitting element according to claim 1, wherein the ratio of the area of the p-electrode to a total area of the hole and the p-type layer is 70% or more.

4. The light emitting element according to claim 1, wherein the overall thickness of the light emitting element is 0.5 mm to 1 mm.

5. The light emitting element according to claim 1, wherein a p-pad electrode is formed on or above the p-electrode and an n-pad electrode is formed on or above the n-electrode, and
a total area of the p-pad electrode and the n-pad electrode is 0.7 mm² or more.

6. The light emitting element according to claim 1, wherein the area of the p-electrode and the diameter of the dot of the n-electrode and the distance between the centers of adjacent dots are set so that the light output is 150 mW or more and the lifetime is 10,000 hours or more when driven at 350 mA.

7. A light emitting device comprising:
the light emitting element according to claim 1; and
a sub-mount with the light emitting element flip-chip mounted and having a reflective layer on the surface of the mounting side, wherein
the reflective layer has a reflectance of 50% or more for ultraviolet light with an emission wavelength of the light emitting element, and
the reflective layer is formed in a region of at least 0 μm to 500 μm outward from the side end surface of the light emitting element, in a plan view.

8. The light emitting device according to claim 7, wherein the reflective layer is formed in an entire region of 0 μm or more outward from the side end surface of the light emitting element, in a plan view.

9. The light emitting device according to claim 7, wherein the sub-mount has a frontside electrode layer connected to the light emitting element,
the reflective layer has an insulating layer as a bottom layer, and
a part of the frontside electrode layer is formed outside the side end surface of the light emitting element, in a plan view.

10. The light emitting device according to claim 7, wherein the reflective layer includes an insulating layer, and
a metal reflective layer formed on or above the insulating layer and made of a metal having a reflectance of 50% or more for ultraviolet light with an emission wavelength of the light emitting element.

11. The light emitting device according to claim 7, wherein the reflective layer includes a DBR reflective layer having a reflectance of 90% or more for ultraviolet light with an emission wavelength of the light emitting element.

12. The light emitting device as according to claim 7, wherein the reflective layer includes:
an insulating layer;
a metal reflective layer formed on or above the insulating layer and made of a metal having a reflectance of 50% or more for ultraviolet light with an emission wavelength of the light emitting element; and
a DBR layer formed on or above the metal reflective layer and having a reflectance of 50% or more for ultraviolet light with an emission wavelength of the light emitting element.

13. The light emitting device according to claim 7, wherein the thickness of the substrate of the light emitting element is 900 μm or more.

14. A light emitting device comprising:
a light emitting element using a group III nitride semiconductor containing Al and having an emission wavelength of 200 nm to 280 nm; and
a flat plate sub-mount with the light emitting element flip-chip mounted and having a reflective layer formed on the surface of the mounting side and a frontside electrode layer connected to the light emitting element, wherein
the reflective layer has an insulating layer as a bottom layer,
a part of the frontside electrode layer is formed outside the side end surface of the light emitting element, in a plan view,
the reflective layer has a reflectance of 50% or more for ultraviolet light with an emission wavelength of the light emitting element, and
the reflective layer is formed in a region of at least 0 μm to 500 μm outward from the side end surface of the light emitting element, in a plan view.
